(19) United States
(12) Patent Application Publication
(10) Pub. No.: US 2021/0265143 A1
(43) Pub. Date: Aug. 26, 2021

(54) SUBSTRATE PROCESSING APPARATUS AND STAGE

(71) Applicant: Tokyo Electron Limited, Tokyo (JP)

(72) Inventors: Hiroki ENDO, Miyagi (JP); Kazuhito YAMADA, Miyagi (JP); Masanori TAKAHASHI, Miyagi (JP)

(21) Appl. No.: 17/178,458

(22) Filed: Feb. 18, 2021

(30) Foreign Application Priority Data
Feb. 21, 2020 (JP) 2020-028240

(51) Int. Cl. H01J 37/32; H01L 21/683; H01L 21/67

(52) U.S. Cl. CPC H01J 37/32724; H01L 21/6833; H01J 2237/334; H01J 37/32091; H01J 2237/2007; H01L 21/67103

(57) ABSTRACT

A substrate processing apparatus for processing a substrate using plasma includes a chamber in which the substrate is accommodated, and a stage arranged inside the chamber and configured to mount the substrate thereon. The stage includes: a base formed by a conductor and configured to allow RF (Radio Frequency) power to flow through the conductor; a substrate holding part provided on the base and configured to hold the substrate; a plurality of heaters provided in the substrate holding part; a heater control part provided inside the base and configured to control electric power to be supplied to each of the plurality of heaters; and an RF filter provided outside the base and connected to a wiring for supplying the electric power to each of the plurality of heaters. The RF filter is provided in common for the plurality of heaters.

### CROSS-REFERENCE TO RELATED APPLICATION

This application is based upon and claims the benefit of priority from Japanese Patent Application No. 2020-028240, filed on Feb. 21, 2020, the entire contents of which are incorporated herein by reference.

### TECHNICAL FIELD

Various aspects and embodiments of the present disclosure relate to a substrate processing apparatus and a stage.

### BACKGROUND

There is known a substrate processing apparatus provided with a plurality of heaters and capable of independently adjusting the temperature of a plurality of regions of a stage on which a semiconductor wafer (hereinafter referred to as a substrate) is mounted (see, e.g., Patent Document 1). In a semiconductor manufacturing process using such a substrate processing apparatus, the uniformity of substrate processing can be improved by adjusting the temperature of the substrate with high accuracy.

### PRIOR ART DOCUMENT

[Patent Document]
Patent Document 1: Japanese Laid-Open Patent Publication No. 2017-228230

### SUMMARY

According to one embodiment of the present disclosure, there is provided a substrate processing apparatus for processing a substrate using plasma, which includes: a chamber in which the substrate is accommodated; and a stage arranged inside the chamber and configured to mount the substrate thereon, wherein the stage includes: a base formed by a conductor and configured to allow RF (Radio Frequency) power to flow through the conductor; a substrate holding part provided on the base and configured to hold the substrate; a plurality of heaters provided in the substrate holding part; a heater control part provided inside the base and configured to control electric power to be supplied to each of the plurality of heaters; and an RF filter provided outside the base and connected to a wiring for supplying the electric power to each of the plurality of heaters, and the RF filter is provided in common for the plurality of heaters.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a schematic sectional view showing an example of a configuration of a substrate processing apparatus according to a first embodiment of the present disclosure.

FIG. 2 is a view showing an example of an upper surface of an electrostatic chuck.

FIG. 3 is an enlarged sectional view showing an example of a detailed structure of a stage.

FIG. 4 is a block diagram showing an example of a functional configuration of a control board according to the first embodiment.

FIG. 5 is a circuit diagram showing an example of a measurement part.

FIG. 6 is a view for explaining a temperature difference between a temperature of a surface of a substrate and temperature of a resistor.

FIG. 7 is a view showing an example of a first correction value table.

FIG. 8 is a diagram showing an example of a second correction value table.

FIG. 9 is a schematic sectional view showing an example of a configuration of the substrate processing apparatus when creating the correction value table.

FIG. 10 is a flowchart showing an example of a process performed by the substrate processing apparatus when creating the correction value table.

FIG. 11 is a flowchart showing an example of temperature control in the first embodiment.

FIG. 12 is a block diagram showing an example of a functional configuration of a control board according to a second embodiment.

FIG. 13 is a view showing an example of a conversion table.

FIG. 14 is a flowchart showing an example of a method of creating the conversion table.

FIG. 15 is a flowchart showing an example of temperature control in the second embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of a substrate processing apparatus and a stage will be described in detail with reference to the drawings. The substrate processing apparatus and the stage disclosed herein are not limited by the embodiments described below.

In a substrate processing apparatus that performs a process using plasma, RF power flows through a stage. Therefore, a portion of the RF power is likely to flow through a wiring for supplying electric power from the outside of the stage to a heater inside the stage. The wiring for supplying electric power to the heater is connected to a power supply via a control device that controls the electric power supplied to the heater.

Since the control device and the power supply device are provided outside the substrate processing apparatus, the wiring serves as an antenna. Thus, there may be a case where a portion of the RF power flowing through the wiring is radiated to the outside of the substrate processing apparatus so that the RF power flows into the power supply device. In order to suppress this, an RF filter is provided on each wiring for supplying electric power to the heater outside the substrate processing apparatus.

In recent semiconductor manufacturing processes, it is required to further improve the temperature uniformity of the substrate along with the progress of miniaturization. In order to further improve the temperature uniformity of the substrate, it is conceivable to further subdivide the independently temperature-controlled regions in the stage on which the substrate is mounted.

As the number of independently temperature-controlled regions increases, the number of wirings for supplying electric power to the heaters provided in the respective regions increases. As the number of wirings for supplying electric power to the heaters increases, the number of RF filters also increases. As a result, the entire substrate processing apparatus becomes larger in size.

Therefore, the present disclosure provides a technique capable of downsizing the substrate processing apparatus.

### First Embodiment

[Configuration of Substrate Processing Apparatus 1]

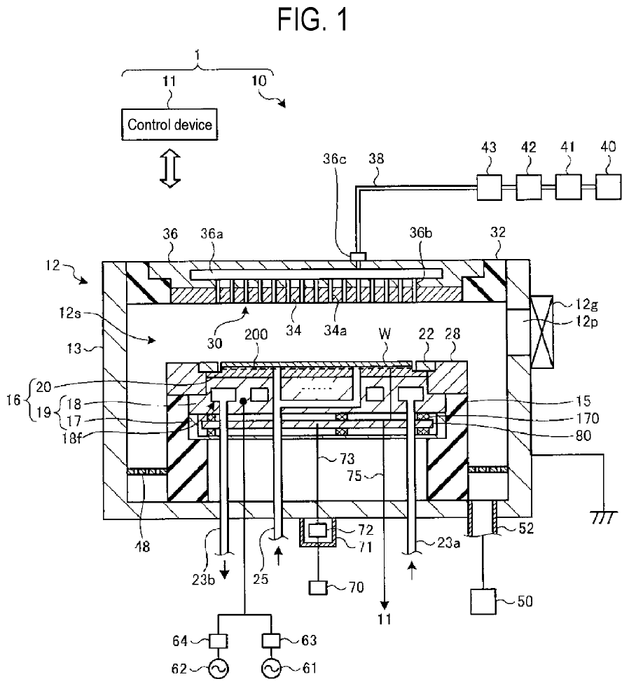

FIG. 1 is a schematic sectional view showing an example of a configuration of a substrate processing apparatus 1 according to a first embodiment of the present disclosure. The substrate processing apparatus 1 includes an apparatus main body 10 and a control device 11 that controls the apparatus main body 10. The substrate processing apparatus 1 according to the present embodiment is, for example, a capacitively coupled plasma etching apparatus.

The apparatus main body 10 includes a chamber 12. The chamber 12 provides an internal space 12s therein. The chamber 12 includes a housing 13 made of, for example, aluminum or the like and formed in a substantially cylindrical shape. The internal space 12s is provided in the housing 13. The housing 13 is electrically grounded. The inner wall surface of the housing 13, i.e., the wall surface that defines the internal space 12s, is coated with a plasma-resistant film formed by, for example, anodizing.

An opening 12p through which a substrate W passes when the substrate W is transferred between the internal space 12s and the outside of the chamber 12 is formed on the side wall of the housing 13. The opening 12p is opened and closed by a gate valve 12g.

A stage 16 on which the substrate W is mounted is provided in the housing 13. The stage 16 is supported by a support part 15 which is made of an insulating material such as quartz or the like and is formed in a substantially cylindrical shape. The support part 15 extends upward from the bottom of the housing 13.

The stage 16 includes a base 19 and an electrostatic chuck 20. The base 19 includes a cover plate 17 and a lower electrode 18. The electrostatic chuck 20 is provided on the lower electrode 18 of the base 19. The substrate W is placed on the electrostatic chuck 20. The electrostatic chuck 20 includes a main body formed of an insulating material and an electrode formed in a film shape. A DC power supply is electrically connected to the electrode of the electrostatic chuck 20. When a voltage is applied to the electrode of the electrostatic chuck 20 from the DC power supply, an electrostatic force is generated on the electrostatic chuck 20, and the substrate W is attracted to and held on the upper surface of the electrostatic chuck 20 by the electrostatic force. The electrostatic chuck 20 is an example of a substrate holding part.

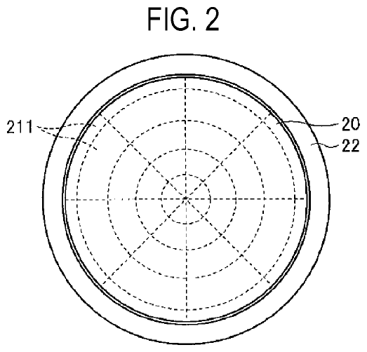

Further, as shown in FIG. 2, for example, the upper surface of the electrostatic chuck 20 is divided into a plurality of divided regions 211. FIG. 2 is a view showing an example of the upper surface of the electrostatic chuck 20. One heater 200 is embedded inside the electrostatic chuck 20 in each of the divided regions 211. By individually controlling the temperatures of the divided regions 211 with the respective heaters 200, it is possible to improve the temperature uniformity of the surface of the substrate W. The heaters 200 may be arranged between the electrostatic chuck 20 and the lower electrode 18.

In the electrostatic chuck 20, there is provided a pipe 25 for supplying a heat transfer gas such as a He gas or the like between the electrostatic chuck 20 and the substrate W. By controlling the pressure of the heat transfer gas supplied between the electrostatic chuck 20 and the substrate W, it is possible to control the thermal conductivity between the electrostatic chuck 20 and the substrate W.

The lower electrode 18 is made of a conductive material such as, for example, aluminum or the like, and formed in a substantially disk shape. In the lower electrode 18, there is formed a flow path 18f through which a refrigerant such as, for example, CFC or the like flows. The refrigerant is supplied from a chiller unit (not shown) into the flow path 18f via a pipe 23a. The refrigerant circulating in the flow path 18f is returned to the chiller unit via a pipe 23b. As the refrigerant whose temperature is controlled by the chiller unit is caused to circulate in the flow path 18f, it is possible to cool the lower electrode 18 to a predetermined temperature.

The cover plate 17 is made of a conductive material such as, for example, aluminum or the like, and formed in a substantially disk shape. The cover plate 17 is arranged below the lower electrode 18 and is electrically connected to the lower electrode 18. A recess is formed in the cover plate 17, and a control board 80 provided with elements such as a microcomputer for controlling the heaters 200 in the electrostatic chuck 20 or the like is arranged in the recess.

The control board 80 is supported by the cover plate 17 and the lower electrode 18 via spacers 170 formed of an insulating material. The control board 80 is surrounded by the cover plate 17 and the lower electrode 18 formed of conductors.

One end of a metal wiring 73 for supplying electric power to each heater 200 is connected to the control board 80. The other end of the metal wiring 73 is connected to a power supply device 70 via a through-hole formed in the bottom of the housing 13 and an RF filter 72. The RF filter 72 is arranged outside the base 19 and provided on the metal wiring 73 for supplying electric power to each heater 200. The RF filter 72 is surrounded by a shield member 71 formed of a conductor. The shield member 71 is electrically connected to the housing 13 and is grounded via the housing 13. The electric power supplied from the power supply device 70 is supplied to the control board 80 via the RF filter 72 and the metal wiring 73.

Further, one end of an optical fiber cable 75 for making communication between the microcomputer provided on the control board 80 and the control device 11 is connected to the control board 80. The other end of the optical fiber cable 75 is connected to the control device 11. Alternatively, the other end of the optical fiber cable 75 may be connected to another microcomputer provided outside the housing 13. In this case, another microcomputer makes communication with the control device 11 via a communication line such as a LAN or the like to relay the communication between the microcomputer of the control board 80 and the control device 11.

An edge ring 22 formed in an annular shape by a conductive material such as, for example, silicon or the like, is provided on the outer peripheral region of the electrostatic chuck 20. The edge ring 22 is sometimes called a focus ring. The edge ring 22 is arranged so as to surround the substrate W mounted on the electrostatic chuck 20.

On the side surface of the stage 16, a cover member 28 formed in a substantially cylindrical shape by an insulating material is provided so as to surround the stage 16. The cover member 28 protects the side surface of the stage 16 from the plasma generated in the internal space 12s.

An upper electrode 30 is provided above the stage 16. The upper electrode 30 is supported on the upper portion of the housing 13 via a member 32 formed of an insulating material. The upper electrode 30 includes a top plate 34 and a top plate holding portion 36. The lower surface of the top plate 34 faces the internal space 12s. The top plate 34 has a plurality of gas discharge holes 34a that penetrate the top plate 34 in the thickness direction. The top plate 34 is made of, for example, silicon or the like. Further, the top plate 34 may be formed of, for example, aluminum having a plasma resistant coating on its surface.

The top plate holding portion 36 holds the top plate 34 in a detachable manner. The top plate holding portion 36 is formed of a conductive material such as, for example, aluminum or the like. A gas diffusion chamber 36a is formed inside the top plate holding portion 36. A plurality of gas holes 36b extend downward from the gas diffusion chamber 36a. The gas holes 36b communicates with the gas discharge holes 34a. The top plate holding portion 36 is provided with a gas introduction port 36c connected to the gas diffusion chamber 36a. One end of a pipe 38 is connected to the gas introduction port 36c.

A gas source group 40 is connected to the other end of the pipe 38 via a valve group 43, a flow rate controller group 42 and a valve group 41. The gas source group 40 includes a plurality of gas sources for supplying gases contained in an etching gas. Each of the valve group 41 and the valve group 43 includes a plurality of valves (e.g., opening/closing valves). The flow rate controller group 42 includes a plurality of flow rate controllers such as, for example, mass flow controllers or the like.

Each gas source included in the gas source group 40 is connected to the pipe 38 via a corresponding valve in the valve group 41, a corresponding flow rate controller in the flow rate controller group 42 and a corresponding valve in the valve group 43. The gas from one or more gas sources selected from the gas sources included in the gas source group 40 is supplied into the gas diffusion chamber 36a at an individually-adjusted flow rate. The gas supplied into the gas diffusion chamber 36a is diffused in the gas diffusion chamber 36a and is supplied into the internal space 12s through the gas holes 36b and the gas discharge holes 34a in the form of a shower.

A baffle plate 48 having a plasma-resistant coating on the surface thereof and made of, for example, aluminum or the like, is provided between the outer wall of the support part 15 and the inner wall of the housing 13. The baffle plate 48 has a plurality of through-holes penetrating the baffle plate 48 in the thickness direction. An exhaust pipe 52 is connected to the bottom of the housing 13 below the baffle plate 48. An exhaust device 50 including a pressure controller such as an automatic pressure control valve or the like and a vacuum pump such as a turbo molecular pump or the like is connected to the exhaust pipe 52. The exhaust device 50 can reduce the pressure in the internal space 12s to a predetermined pressure.

A first RF power supply 61 is connected to the base 19 via a first matcher 63. The first RF power supply 61 is a power supply that generates first RF power for plasma generation. The frequency of the first RF power is a frequency in the range of 27 to 100 MHz, for example, a frequency of 60 MHz. The first matcher 63 includes a matching circuit for matching the output impedance of the first RF power supply 61 with the impedance on the load side (e.g., the base 19 side). The first RF power supply 61 may be connected to the upper electrode 30 instead of the base 19 via the first matcher 63.

Further, a second RF power supply 62 is connected to the base 19 via a second matcher 64. The second RF power supply 62 is a power supply that generates second RF power for bias for drawing ions into the substrate W. The frequency of the second RF power is lower than the frequency of the first RF power and is a frequency in the range of 400 kHz to 13.56 MHz, for example, a frequency of 400 kHz. The second matcher 64 has a matching circuit for matching the output impedance of the second RF power supply 62 with the impedance on the load side (e.g., the base 19 side).

The control device 11 includes a memory, a processor and an input/output interface. Data such as recipes or the like and programs are stored in the memory. The memory is, for example, a RAM (Random Access Memory), a ROM (Read Only Memory), an HDD (Hard Disk Drive), an SSD (Solid State Drive), or the like. By executing the program read from the memory, the processor controls each part of the apparatus main body 10 via the input/output interface based on the data such as the recipes or the like stored in the memory. The processor is a CPU (Central Processing Unit), a DSP (Digital Signal Processor), or the like.

When plasma etching is performed by the substrate processing apparatus 1, the gate valve 12g is opened, the substrate W is loaded into the housing 13 by a transfer robot (not shown) and mounted on the electrostatic chuck 20. Then, the gas in the housing 13 is exhausted by the exhaust device 50, one or more gases from the gas source group 40 are supplied into the internal space 12s at a predetermined flow rate, and the pressure in the internal space 12s is regulated to a predetermined pressure.

Further, the lower electrode 18 is cooled by supplying a refrigerant, the temperature of which is controlled by a chiller unit (not shown), into the flow path 18f. Moreover, the electric power supplied from the power supply device 70 to the heaters 200 provided in the respective divided regions 211 of the electrostatic chuck 20 is controlled by the microcomputer of the control board 80. In addition, the pressure of the heat transfer gas supplied between the electrostatic chuck 20 and the substrate W is controlled by the control device 11. As a result, the temperature of the substrate W mounted on the electrostatic chuck 20 is adjusted to a predetermined temperature.

Then, the first RF power from the first RF power supply 61 and the second RF power from the second RF power supply 62 are supplied to the base 19. As a result, an RF electric field is formed between the upper electrode 30 and the base 19, and the gas supplied to the internal space 12s is turned into plasma. Then, the substrate W is etched by ions, radicals and the like contained in the plasma generated in the internal space 12s.

[Details of Stage 16]

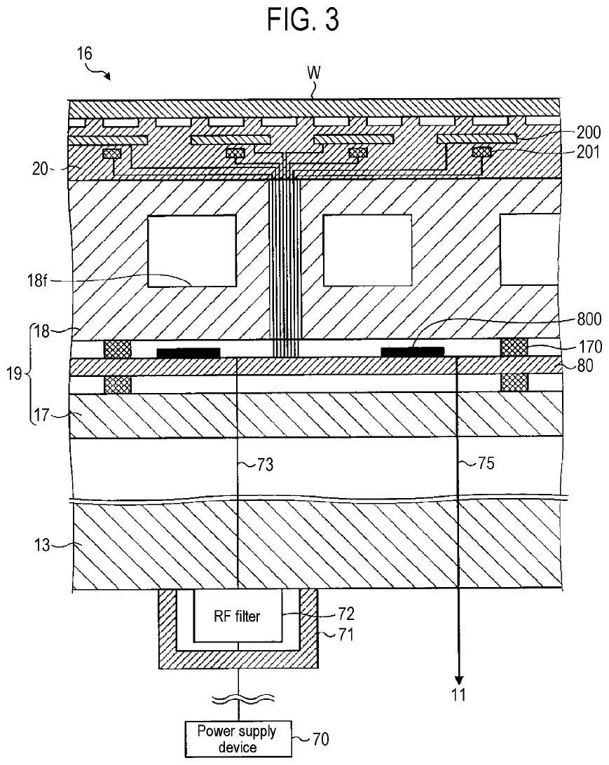

FIG. 3 is an enlarged sectional view showing an example of the detailed structure of the stage 16. In the present embodiment, the electrostatic chuck 20 is provided with a heater 200 and a resistor 201 for each divided region 211. In the present embodiment, the resistor 201 is arranged between the heater 200 and the lower electrode 18. The resistance value of the resistor 201 is changed according to the temperature. In the present embodiment, the resistor 201 is, for example, a thermistor.

The heater 200 and the resistor 201 provided in each divided region 211 are connected to the control board 80 via a wiring arranged in the through-hole formed in the lower electrode 18. In the control board 80, there is provided elements 800 such as microcomputers and the like that control the electric power supplied to the heater 200 arranged in the corresponding divided region 211 based on the temperature measured by using the resistor 201 arranged in each divided region 211.

Since the control board 80 is surrounded by the base 19 formed of a conductor, almost no RF power flows through the control board 80 even if RF power is supplied to the base 19. Therefore, even if the control board 80 is not provided with a filter for removing the RF power, the elements 800 are not erroneously operated due to the RF power.

On the other hand, the metal wiring 73 for supplying electric power to each heater 200 is drawn out from the inside of the base 19 to the outside of the base 19, and is not surrounded by the base 19. As a result, the RF power supplied to the base 19 easily flows through the metal wiring 73. Therefore, the RF filter 72 is connected to the metal wiring 73.

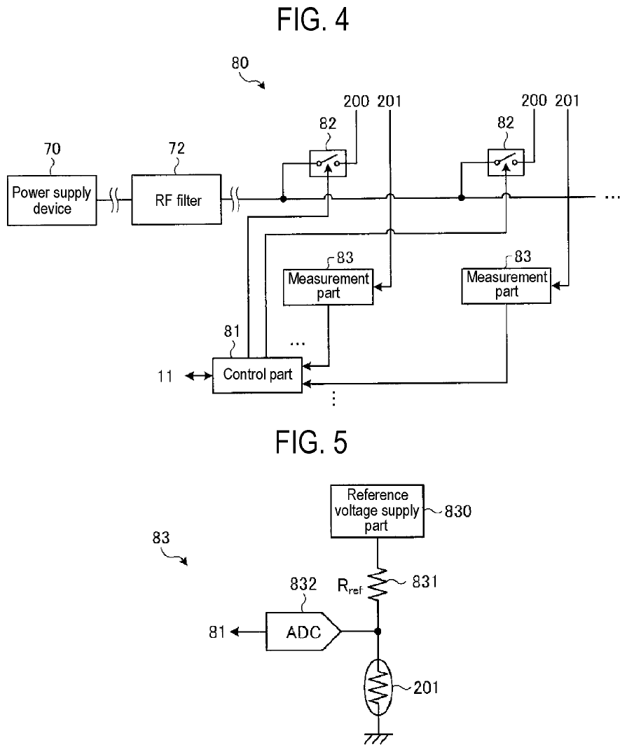

FIG. 4 is a block diagram showing an example of the functional configuration of the control board 80 according to the first embodiment. The control board 80 is provided with a control part 81, a plurality of switches 82 and a plurality of measurement parts 83 as the elements 800. In the present embodiment, one switch 82 and one measurement part 83 are provided for each heater 200 and each resistor 201.

In response to a control signal from the control part 81, each switch 82 controls the supply and cutoff of the electric power supplied from the power supply device 70 to the corresponding heater 200 via the RF filter 72.

Each measurement part 83 measures a voltage corresponding to the temperature of the corresponding resistor 201, and outputs a measured voltage value to the control part 81.

FIG. 5 is a circuit diagram showing an example of the measurement part 83. The measurement part 83 includes a reference voltage supply part 830, a reference resistor 831 and an ADC (Analog Digital Converter) 832. The reference voltage supply part 830 supplies a reference voltage Vref to the reference resistor 831 and the resistor 201. The ADC 832 converts the voltage value applied across the resistor 201 from an analog signal into a digital signal. Then, the ADC 832 outputs the voltage value converted into the digital signal to the control part 81.

The control part 81 receives the set temperature of the base 19 and the set temperature of the substrate W corresponding to each divided region 211 from the control device 11. Then, the control part 81 measures the temperature of the resistor 201 (i.e., the temperature of the divided region 211) for each divided region 211 based on the voltage value of the resistor 201 provided in the divided region 211. In the present embodiment, the resistor 201 is a thermistor. The temperature of the thermistor and the resistance value of the thermistor have, for example, a relationship as represented in the following equation (1).

$${R}_{thermistor} = {R}_{25} \times {e}^{\{ B ( \frac{1}{Temp} \frac{1}{25 + 273.15} ) \}} \qquad ( 1 )$$

In the above equation (1), Rₜₕₑᵣₘₒₛₜₒᵣ denotes the resistance value of the thermistor, R₂₅ denotes the resistance value of the thermistor at 25 degrees C., B denotes the B constant of the thermistor, and Temp denotes the temperature of the divided region 211 to be measured.

The voltage value outputted from the ADC 832 is represented by, for example, the following equation (2).

$${V}_{ADC} = \frac{{V}_{ref}}{{R}_{ref} + {R}_{thermistor}} \times {R}_{thermistor} \qquad ( 2 )$$

In the above equation (2), V_{ADC} denotes the voltage value outputted from the ADC 832, V_{ref} denotes the reference voltage value supplied from the reference voltage supply part 830, and R_{ref} denotes the resistance value of the reference resistor 831.

From the above equations (1) and (2), the temperature Temp of the divided region 211 to be measured is represented by, for example, the following equation (3).

$$Temp = \frac{1}{\frac{In ( \frac{{V}_{ADC} \times {R}_{ref}}{{V}_{ref} - {V}_{ADC}} \times \frac{1}{{R}_{25}} )}{B} + \frac{1}{15 + 273.15}} \qquad ( 3 )$$

In the above equation (3), the values except for the voltage value V_{ADC} outputted from the ADC 832 are known. Therefore, by acquiring the voltage value V_{ADC} from the ADC 832, the control part 81 can measure the temperature Temp of the divided region 211 provided with the resistor 201 which is a thermistor.

Then, the control part 81 controls the electric power to be supplied to the corresponding heater 200 for each divided region 211 by controlling the corresponding switch 82 based on the set temperature of the base 19, the set temperature of the substrate W and the measured temperature Temp. For example, when the measured temperature for each divided region 211 is lower than a target temperature, the control part 81 controls the corresponding switch 82 so that the corresponding heater 200 is more frequently supplied with electric power. On the other hand, when the measured temperature is higher than the target temperature, the control part 81 controls the corresponding switch 82 so that the corresponding heater 200 is less frequently supplied with electric power. The control part 81 is an example of a heater control part.

In the present embodiment, one RF filter 72 is provided in common for a plurality of heaters 200, for example, as shown in FIG. 4. If the control board 80 is provided outside the base 19, the wirings for connecting the switches 82 and the heaters 200 and the wirings for connecting the measurement parts 83 and the resistors 201 as many as the number of the divided regions 211 are drawn out to the control board 80 outside the base 19. When the number of the divided regions 211 is several tens or more, the number of the wirings drawn out to the outside of the base 19 may be 100 or more.

Since the wiring drawn out to the outside of the base 19 passes through the base 19, the RF power supplied to the base 19 can easily flow. Further, since each wiring is a wiring for individually supplying electric power to the heater 200 or a wiring for individually measuring the resistance value of the resistor 201, it is difficult to commonly provide a filter for removing RF. Therefore, a filter for removing RF is provided individually for each wiring.

When the number of the wirings drawn out to the outside of the base 19 is 100 or more, it is difficult to secure a space for arranging filters for removing RF. In order to further increase the in-plane uniformity of the temperature control of the substrate W, it is conceivable to further increase the number of the divided regions 211. In this case, the number of the wirings drawn out to the outside of the base 19 is further increased. This makes it further difficult to secure a space for arranging the filters for removing RF.

On the other hand, in the present embodiment, the control board 80 is arranged in the base 19 to which the RF power is supplied, and is surrounded by the base 19. As a result, almost no RF power flows through the wiring that connects the switch 82 and the heater 200 and through the wiring that connects the measurement part 83 and the resistor 201. Therefore, it is not necessary to provide a filter for removing RF in the wiring that connects the switch 82 and the heater 200 and the wiring that connects measurement part 83 and the resistor 201. This makes it possible to reduce the size of the substrate processing apparatus 1.

[Difference Between the Surface Temperature of the Substrate W and the Measured Temperature]

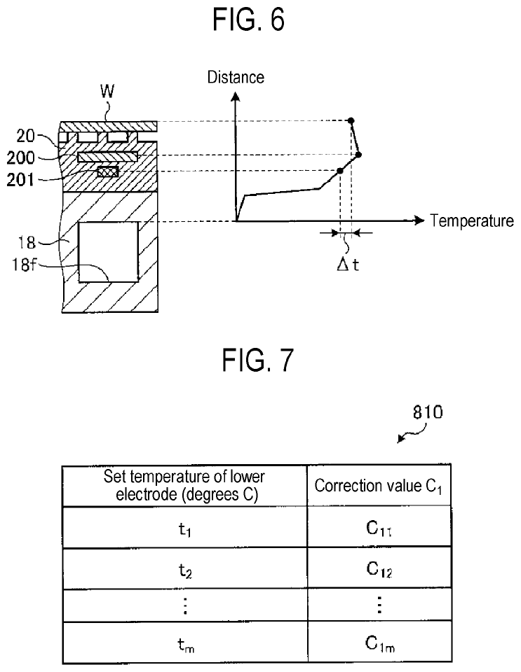

Further, in the present embodiment, the resistor 201 is arranged between the heater 200 and the lower electrode 18, and the temperature of the lower electrode 18 is set to a temperature lower than that of the heater 200. Therefore, the temperature of the surface of the substrate W and the temperature measured by the resistor 201 have a relationship as shown in FIG. 6, for example. FIG. 6 is a view for explaining the temperature difference Δt between the surface temperature of the substrate W and the temperature of the resistor 201. In FIG. 6, there is shown the relationship between the distance from the upper end of the flow path 18f of the lower electrode 18 and the temperature.

In the lower electrode 18, the temperature gradually rises as the distance from the flow path 18f increases. On the other hand, in the contact portion between the lower electrode 18 and the electrostatic chuck 20, the thermal conductivity is lower than that inside the lower electrode 18 and the electrostatic chuck 20 due to the surface roughness and the like. Therefore, the temperature rises sharply in the contact portion between the lower electrode 18 and the electrostatic chuck 20. Furthermore, in the electrostatic chuck 20, the temperature gradually rises to the position of the heater 200 as the distance from the flow path 18f increases. The temperature reaches the maximum value at the position of the heater 200.

Then, in the electrostatic chuck 20, the temperature gradually decreases as the distance from the flow path 18f and the electrostatic chuck 20 increases. Further, even inside the substrate W, the temperature gradually decreases as the distance from the flow path 18f and the electrostatic chuck 20 increases. As a result, there may be a temperature difference Δt between the temperature measured by the resistor 201 and the temperature on the surface of the substrate W.

Therefore, in the present embodiment, the temperature difference Δt between the surface of the substrate W and the resistor 201 is measured, and a correction value is created based on the measured temperature difference Δt. Then, the temperature measured by the resistor 201 is corrected based on the created correction value.

For example, a case is considered where the temperature of the substrate W is controlled to 50 degrees C. The temperature calculated based on the resistance value of the resistor 201 is the temperature of the resistor 201. When the temperature of the resistor 201 is 2 degrees C. lower than the temperature of the surface of the substrate W, if the electric power supplied to the heater 200 is controlled so that the temperature calculated based on the resistance value of the resistor 201 becomes 50 degrees C., the temperature of the surface of the substrate W may become 52 degrees C.

Therefore, in the present embodiment, the temperature difference obtained by subtracting the temperature of the resistor 201 from the temperature of the surface of the substrate W is calculated as the correction value. In the previous example, the temperature difference is 2 degrees C. Then, the value obtained by subtracting the correction value C from the set temperature t_{W} of the substrate W is determined as a set temperature t_{R} of the divided region 211 measured by the resistor 201. In the previous example, t_{R}=t_{W}−C.

The control part 81 controls the electric power supplied to the corresponding heater 200 so that the temperature measured by the resistor 201 becomes equal to the determined set temperature t_{R}. As a result, in the previous example, the surface of the substrate W is controlled to 50 degrees C. by controlling the set temperature t_{R} of the divided region 211 measured by the resistor 201 to become 50−2=48 degrees C.

In this regard, the correction value C may differ depending on the temperature of the lower electrode 18 or the temperature difference between the lower electrode 18 and the substrate W. Therefore, in the present embodiment, a first correction value C₁ is measured for each set temperature of the lower electrode 18, and a second correction value C₂ is measured in advance for each temperature difference between the lower electrode 18 and the substrate W. Then, the control part 81 specifies the correction value C based on the first correction value C₁ and the second correction value C₂ thus measured.

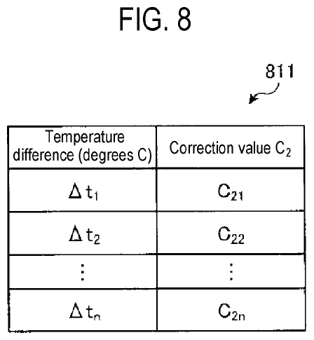

In the present embodiment, the control part 81 holds, for example, a first correction value table 810 as shown in FIG. 7 and a second correction value table 811 as shown in FIG. 8, for each divided region 211. In the first correction value table 810, for example, as shown in FIG. 7, the first correction value C₁ is stored in association with the set temperature of the lower electrode 18. Further, in the second correction value table 811, for example, as shown in FIG. 8, the second correction value C₂ is stored in association with the temperature difference between the set temperature of the lower electrode 18 and the set temperature of the surface of the substrate W. The method of creating the first correction value table 810 and the second correction value table 811 and the method of correcting the temperature measured by the resistor 201 will be described later. In the following, the first correction value table 810 and the second correction value table 811 may be collectively referred to as correction value tables without being distinguished from one another.

[Configuration of the Substrate Processing Apparatus 1 when Creating the Correction Value Tables]

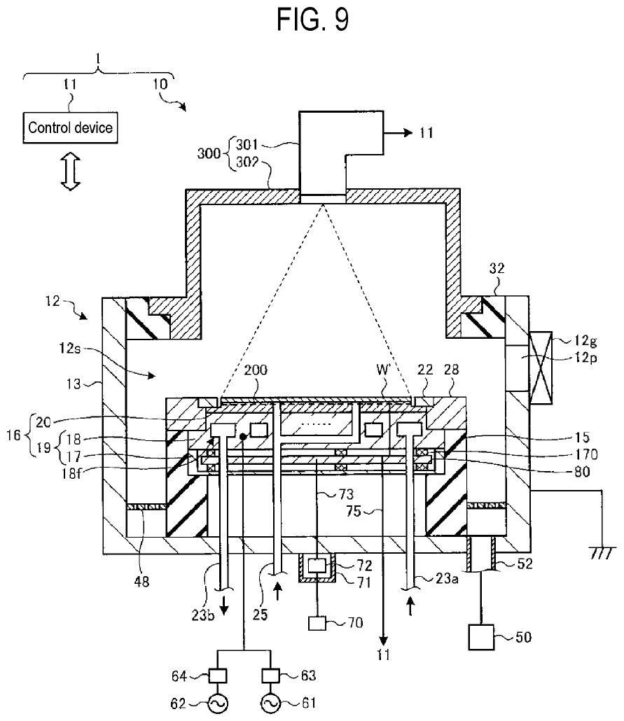

When creating the first correction value table 810 and the second correction value table 811, for example, a substrate processing apparatus 1 having a configuration shown in FIG. 9 is used. FIG. 9 is a schematic cross-sectional view showing an example of the configuration of the substrate processing apparatus 1 when creating the correction value tables. The substrate processing apparatus 1 shown in FIG. 9 is an apparatus in which the upper electrode 30 is removed from the substrate processing apparatus 1 shown in FIG. 1 and a calibration unit 300 is attached. Except for the points described below, in FIG. 9, the members having the same reference numerals as those in FIG. 1 are the same as or have the same functions as the members shown in FIG. 1. Therefore, the description thereof will be omitted.

When the first correction value table 810 and the second correction value table 811 are created, a dummy substrate W′ whose surface is colored black is mounted on the electrostatic chuck 20, and a temperature distribution of the surface of the dummy substrate W is measured. The calibration unit 300 includes an IR (Infrared) camera 301 and a cover member 302. The cover member 302 supports the IR camera 301 so that the imaging direction of the IR camera 301 faces the direction of the dummy substrate W on the electrostatic chuck 20. The IR camera 301 measures the temperature of the surface of the dummy substrate W based on the radiation amount of infrared ray emitted from the surface of the dummy substrate W. Then, the IR camera 301 outputs the measured temperature information of the surface of the dummy substrate W to the control device 11.

[Process of Creating Correction Value Tables]

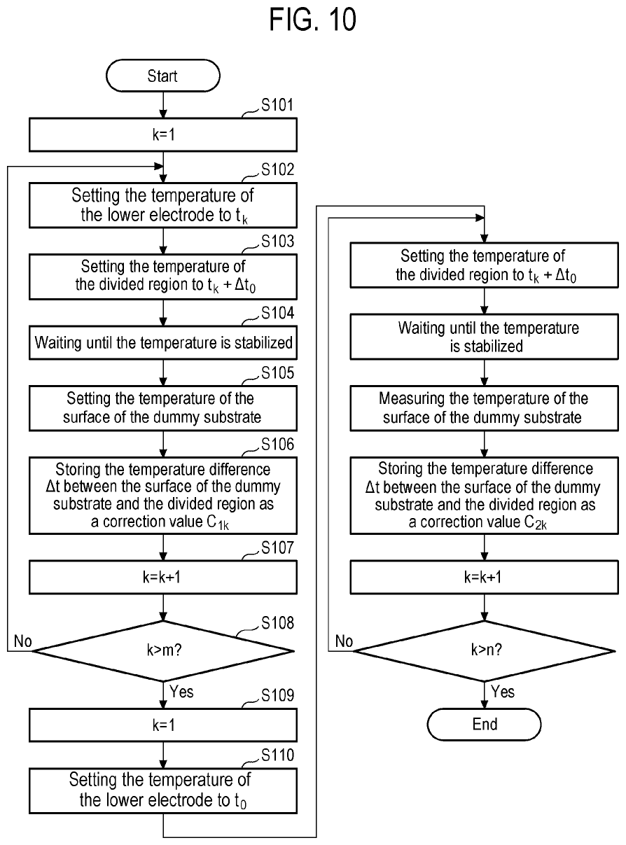

FIG. 10 is a flowchart showing an example of a process performed by the substrate processing apparatus 1 when creating correction value tables. The process shown in FIG. 10 is implemented by controlling each part of the apparatus main body 10 with the control device 11 in the substrate processing apparatus 1 illustrated in FIG. 9.

First, the control device 11 initializes the value of a variable k to 1 (S100). Then, the control device 11 sets the temperature of the lower electrode 18 to tₖ (S101). In step S100, the control device 11 controls a chiller unit (not shown) so that the temperature of the refrigerant circulating in the flow path 18f of the lower electrode 18 becomes equal to tₖ.

Next, the control device 11 sets the temperature of each divided region 211 to tₖ+Δt₀ (S102). In the present embodiment, Oto is, for example, 50 degrees C. In step S101, the control device 11 transmits the set temperature tₖ+Δt₀ to the control part 81 of the control board 80 for each divided region 211. The control part 81 controls the electric power to be supplied to the heater 200 for each divided region 211 so that the temperature of the divided region 211 measured based on the voltage value of the resistor 201 becomes equal to the set temperature tₖ+Δt₀.

Then, the control device 11 waits until the temperatures of the lower electrode 18, the electrostatic chuck 20 and the dummy substrate W′ are stabilized (S103).

Next, the control device 11 controls the IR camera 301 to measure the temperature of the surface of the dummy substrate W′ (S104).

Next, the control device 11 calculates a temperature difference Δt between the surface of the dummy substrate W and the divided region 211 for each divided region 211. Then, the control device 11 stores the calculated temperature difference Δt for each divided region 211 as a correction value C₁ₖ in the first correction value table 810 (S105).

Next, the control device 11 increases the value of the variable k by 1 (S106), and determines whether or not the value of the variable k is larger than the value of a constant m (S107). The constant m is the number of the first correction values C₁ stored in the first correction value table 810. When the value of the variable k is equal to or less than the value of the constant m (S107: No), the control device 11 executes the process of step S101 again.

On the other hand, when the value of the variable k is larger than the value of the constant m (S107: Yes), the control device 11 initializes the value of the variable k to 1 again (S108). Then, the control device 11 sets the temperature of the lower electrode 18 to t₀ (S109). In the present embodiment, t₀ is, for example, 10 degrees C. In step S109, the control device 11 controls a chiller unit (not shown) so that the temperature of the refrigerant circulating in the flow path 18f of the lower electrode 18 becomes equal to t₀.

Next, the control device 11 sets the temperature of each divided region 211 to t₀+Δtₖ (S110). In step S110, the control device 11 transmits the set temperature t₀+Δtₖ to the control part 81 of the control board 80 for each divided region 211. The control part 81 controls the electric power to be supplied to the heater 200 for each divided region 211 so that the temperature of the divided region 211 measured based on the voltage value of the resistor 201 becomes equal to the set temperature t₀+Δtₖ.

Then, the control device 11 waits until the temperatures of the lower electrode 18, the electrostatic chuck 20 and the dummy substrate W are stabilized (S111).

Next, the control device 11 controls the IR camera 301 to measure the temperature of the surface of the dummy substrate W′ (S112).

Next, the control device 11 calculates a temperature difference Δt between the surface of the dummy substrate W and the divided region 211 for each divided region 211. Then, the control device 11 stores the calculated temperature difference Δt for each divided region 211 as a correction value C₂ₖ in the second correction value table 811 (S113).

Next, the control device 11 increases the value of the variable k by 1 (S114), and determines whether or not the value of the variable k is larger than the value of a constant n (S115). The constant n is the number of the second correction values C₂ stored in the second correction value table 811. When the value of the variable k is equal to or less than the value of the constant n (S115: No), the control device 11 executes the process shown in step S110 again. On the other hand, when the value of the variable k is larger than the value of the constant n (S115: Yes), the control device 11 terminates the process shown in the flowchart.

[Temperature Control During the Processing of the Substrate W]

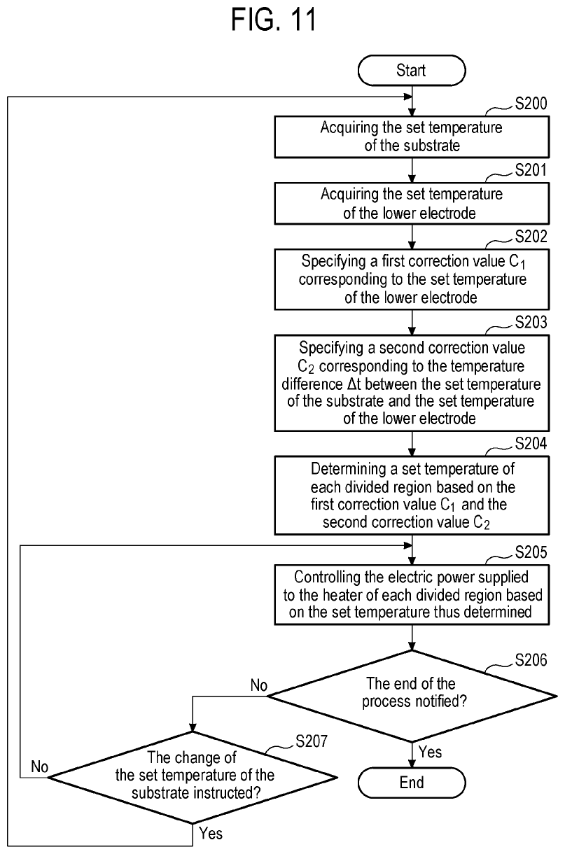

FIG. 11 is a flowchart showing an example of the temperature control according to the first embodiment. The process illustrated in FIG. 11 is implemented by causing the control part 81 to control each part of the control board 80 in the substrate processing apparatus 1 illustrated in FIG. 1. Before the process illustrated in FIG. 11 is started, the control part 81 holds the first correction value table 810 and the second correction value table 811 created by the process illustrated in FIG. 10.

First, the control part 81 acquires the set temperature of the substrate W to be processed from the control device 11 (S200). Further, the control part 81 acquires the set temperature of the lower electrode 18 from the control device 11 (S201). Then, the control part 81 refers to the first correction value table 810 and specifies the first correction value C₁ corresponding to the set temperature of the lower electrode 18 acquired in step S201 for each divided region 211 (S202). Then, the control part 81 refers to the second correction value table 811 and specifies a second correction value C₂ corresponding to the temperature difference Δt between the set temperature of the substrate W and the set temperature of the lower electrode 18 for each divided region 211 (S203).

Next, the control part 81 determines a set temperature of each divided region 211 based on the first correction value C₁ and the second correction value C₂ thus specified (S204). In step S204, the control part 81 determines the set temperature t_{R} of each divided region 211, for example, based on the following equation (4).

$${t}_{R} = {t}_{W} - \frac{{C}_{1} + {C}_{2}}{2} \qquad ( 4 )$$

In the above equation (4), t_{W} denotes the set temperature of the substrate W, C₁ denotes the first correction value C₁, and C₂ denotes the second correction value C₂.

Next, the control part 81 controls the electric power to be supplied to the heater 200 of each divided region 211 based on the set temperature t_{R} determined in step S204 (S205).

Next, the control part 81 determines whether or not the end of the process is notified from the control device 11 (S206). When the end of the process is notified (S206: Yes), the process shown in the flowchart comes to an end.

On the other hand, when the end of the process is not notified (S206: No), the control part 81 determines whether or not the change of the set temperature of the substrate W is instructed by the control device 11 (S207). When the change of the set temperature of the substrate W is not instructed (S207: No), the control part 81 executes the process shown in step S205 again. On the other hand, when the change of the set temperature of the substrate W is instructed (S207: Yes), the control part 81 executes the process shown in step S200 again.

The first embodiment has been described above. As described above, the substrate processing apparatus 1 according to the present embodiment is a substrate processing apparatus 1 that processes the substrate W using plasma, and includes the chamber 12 in which the substrate W is accommodated, and the stage 16 provided inside the chamber 12 and on which the substrate W is mounted thereon. The stage 16 includes the base 19, the electrostatic chuck 20, the heaters 200, the control part 81 and the RF filter 72. The base 19 is formed of a conductor through which the RF power flows. The electrostatic chuck 20 is provided on the base 19 to hold the substrate W. The heaters 200 are provided in the electrostatic chuck 20. The control part 81 is provided inside the base 19 to control the electric power supplied to each of the heaters 200. The RF filter 72 is provided outside the base 19 and is connected to the metal wiring 73 for supplying electric power to the electrostatic chuck 20. Further, one RF filter 72 is provided in common for the heaters 200. As a result, it is possible to reduce the size of the substrate processing apparatus 1.

Further, in the above-described embodiment, the stage 16 includes the resistors 201 arranged in the vicinity of the respective heaters 200 and configured so that the resistance values thereof are changed depending on the temperature, and the measurement parts 83 configured to measure the resistance values of the respective resistors 201. The control part 81 controls the supply of electric power to the corresponding heater 200 based on the temperature corresponding to the resistance value measured by the measurement part 83. Therefore, the temperature of the region of the substrate W corresponding to the region where each heater 200 is provided can be controlled with high accuracy.

Further, in the above-described embodiment, each resistor 201 is arranged between the corresponding heater 200 and the base 19. As a result, the heat of the heater 200 can be efficiently transferred to the substrate W.

Further, in the above-described embodiment, the control part 81 corrects the temperature corresponding to the resistance value of each resistor 201 based on the temperature difference between the temperature corresponding to the resistance value of the resistor 201 and the temperature of the substrate at the position corresponding to the position where the resistor 201 is provided, and controls the supply of electric power to the corresponding heater 200 based on the corrected temperature. This makes it possible to more accurately control the temperature of the substrate W.

Further, in the above-described embodiment, the resistor 201 is a thermistor. As a result, the temperature of the substrate W can be controlled with high accuracy.

Further, in the above-described embodiment, the stage 16 arranged inside the chamber 12 of the substrate processing apparatus 1 for processing the substrate using plasma and configured to mount the substrate W thereon includes the base 19, the electrostatic chuck 20, the heaters 200, the control part 81 and the RF filter 72. The base 19 is formed of a conductor through which RF power flows. The electrostatic chuck 20 is provided on the base 19 to hold the substrate W. The heaters 200 are provided in the electrostatic chuck 20. The control part 81 is provided inside the base 19 to control the electric power to be supplied to each of the heaters 200. The RF filter 72 is provided outside the base 19 and is connected to the metal wiring 73 for supplying electric power to each of the heaters 200. Further, one RF filter 72 is provided in common for the heaters 200. This makes it possible to reduce the size of the stage 16.

### Second Embodiment

In the first embodiment, the temperature of the divided region 211 provided with the resistor 201 is measured based on the resistance value of the resistor 201 provided separately from the heater 200. On the other hand, in the present embodiment, the temperature of the divided region 211 provided with the heater 200 is measured based on the resistance value of the heater 200. As a result, the resistor 201 becomes unnecessary. This makes it possible to reduce the size of the stage 16.

Hereinafter, the differences from the first embodiment will be mainly described. Since the configuration of the substrate processing apparatus 1 is similar to that of the substrate processing apparatus 1 according to the first embodiment described with reference to FIGS. 1 to 3, the description thereof will be omitted.

[Functional Block of the Control Board 80]

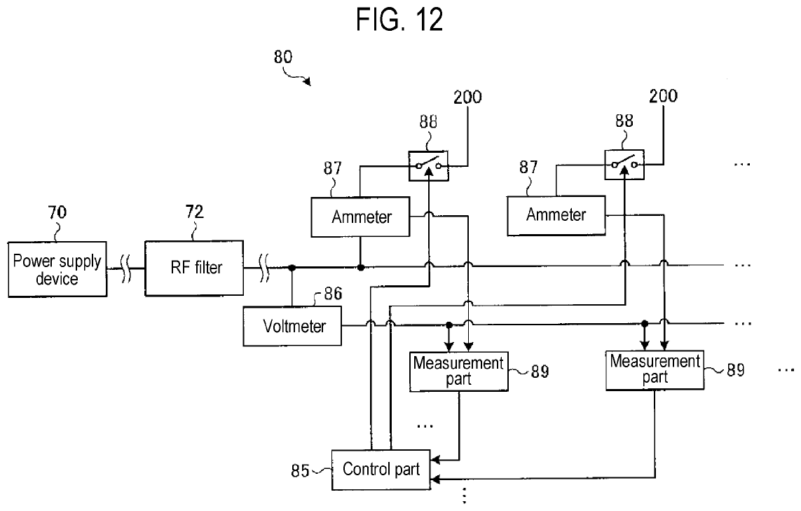

FIG. 12 is a block diagram showing an example of the functional configuration of the control board 80 according to the second embodiment. The control board 80 is provided with a control part 85, a voltmeter 86, a plurality of ammeters 87, a plurality of switches 88 and a plurality of measurement parts 89 as elements 800. The ammeters 87, the switches 88 and the measurement parts 89 are provided one for each of the heaters 200.

Each of the switches 88 controls the supply and cutoff of the electric power to the corresponding heater 200 via the RF filter 72 in response to the control signal from the control part 85.

The voltmeter 86 measures the voltage supplied to each of the heaters 200, and outputs the measured value of the voltage to each of the measurement parts 89.

Each of the ammeters 87 measures the current flowing through the heater 200 when electric power is supplied to the heater 200 by the switch 88, and outputs the measured value of the current to the corresponding measurement part 89.

Each of the measurement parts 89 calculates a resistance value of the corresponding heater 200 by using the measured value of the voltage outputted from the voltmeter 86 and the measured value of the current outputted from the corresponding ammeter 87. Then, each of the measurement parts 89 outputs the calculated resistance value to the control part 85.

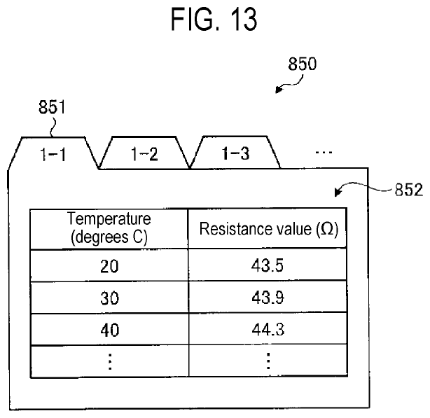

The control part 85 holds a conversion table 850 as shown in FIG. 13, for example. FIG. 13 is a view showing an example of the conversion table 850. In the conversion table 850, an individual table 852 is stored for each identifier 851 that identifies each divided region 211. In each individual table 852, the resistance value of the heater 200 arranged in the divided region 211 is stored in association with the temperature of the divided region 211 identified by the identifier 851.

The control part 85 acquires the resistance value measured by the measurement part 89 for the heater 200 provided in each divided region 211. Then, the control part 85 extracts the individual table 852 corresponding to the acquired resistance value from the conversion table 850, and refers to the extracted individual table 852 to specify the temperature corresponding to the acquired resistance value. When the same resistance value as the acquired resistance value is not stored in the individual table 852, the control part 85 linearly interpolates the value of the resistance value close to the acquired resistance value to thereby specify the temperature corresponding to the acquired resistance value.

Then, the control part 85 corrects the specified temperature for each divided region 211 by the same method as in the first embodiment. Then, the control part 85 controls the corresponding switch 88 for each divided region 211 so that the corrected temperature of each divided region 211 becomes equal to the set temperature of the substrate W notified from the control device 11. Thus, the control part 85 controls the supply of electric power to the corresponding heater 200.

[Creation of the Conversion Table 850]

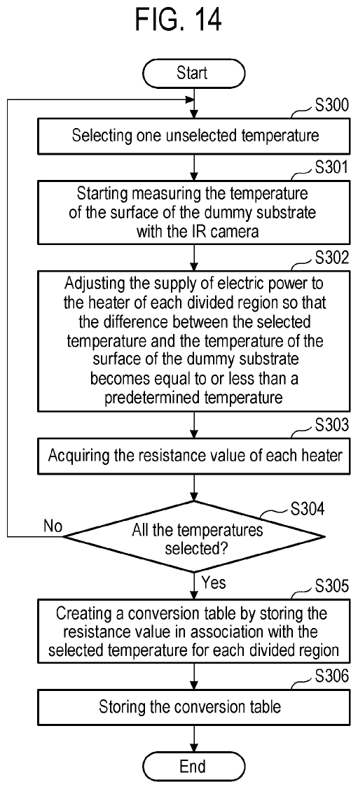

FIG. 14 is a flowchart showing an example of a method of creating the conversion table 850. The process illustrated in FIG. 14 is implemented by causing the control device 11 to control each part of the apparatus main body 10 in the substrate processing apparatus 1 illustrated in FIG. 9.

First, the control device 11 selects one unselected temperature from the plurality of temperatures stored in the conversion table 850 (S300).

Next, the control device 11 controls the IR camera 301 and starts measuring the temperature of the surface of the dummy substrate W′ (S301).

Next, the control device 11 adjusts the supply of electric power to the heater 200 of each divided region 211 so that the difference between the temperature selected in step S300 and the temperature of the surface of the dummy substrate W′ becomes equal to or less than a predetermined temperature (e.g., a temperature of less than 0.1 degrees C.) (S302). In step S302, the control device 11 instructs the control part 85 to increase or decrease the electric power to be supplied to the heater 200 of each divided region 211 based on the temperature of the surface of the dummy substrate W measured by the IR camera 301. The control part 85 controls the switch 88 corresponding to each divided region 211 in response to an instruction from the control device 11.

When the difference between the temperature selected in step S300 and the temperature of the surface of the dummy substrate W is equal to or less than the predetermined temperature, the control device 11 acquires the resistance value of the heater 200 in each divided region 211 from the control part 85 (S303).

Next, the control device 11 determines whether or not all the temperatures stored in the conversion table 850 are selected (S304). If there is an unselected temperature (S304: No), the process shown in step S300 is executed again.

On the other hand, when it is determined that all the temperatures are selected (S304: Yes), the control device 11 creates a conversion table 850 by storing the resistance value of the heater 200 in the individual table 852 in association with the selected temperature for each divided region 211 (S305). Then, the control device 11 stores the created conversion table in the control part 85 (S306). Then, the process shown in the flowchart ends.

[Temperature Control during the Processing of the Substrate W]

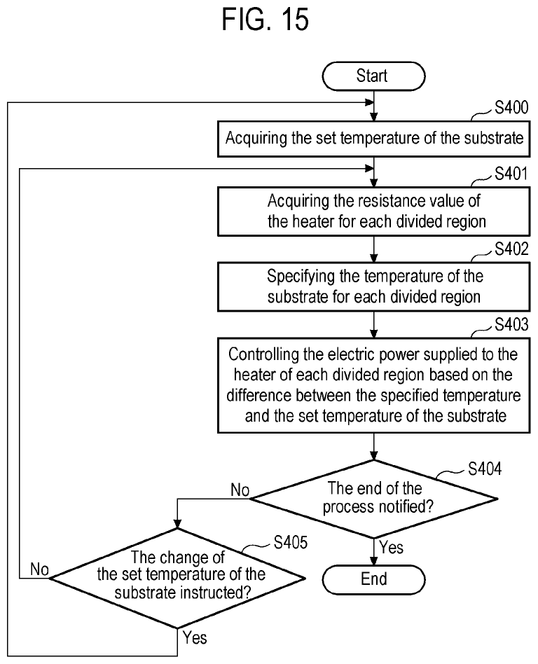

FIG. 15 is a flowchart showing an example of the temperature control according to the second embodiment. The process illustrated in FIG. 15 is implemented by causing the control part 85 to control each part of the control board 80 in the substrate processing apparatus 1 illustrated in FIG. 1. The control part 85 holds the conversion table 850 created by the process illustrated in FIG. 14 before the process illustrated in FIG. 15 is started.

First, the control part 85 acquires the set temperature of the substrate W to be processed from the control device 11 (S400). Then, the control part 85 acquires the resistance value of the heater 200 for each divided region 211 from the measurement part 89 (S401).

Next, the control part 85 refers to the conversion table 850 and specifies the temperature of the region of the substrate W corresponding to the divided region 211 for each divided region 211 (S402). Then, the control part 85 controls the supply of electric power to the heater 200 for each division region 211 based on the difference between the temperature specified in step S402 and the set temperature of the substrate W acquired in step S400 (S403). For example, the control part 85 controls the supply of electric power to the heater 200 for each division region 211 so that the difference between the temperature specified in step S402 and the set temperature of the substrate W acquired in step S400 becomes equal to or lower than a predetermined temperature (e.g., a temperature of less than 0.1 degrees C.).

Next, the control part 85 determines whether or not the end of the process is notified from the control device 11 (S404). When it is determined that the end of the process is notified (S404: Yes), the process shown in the flowchart ends.

On the other hand, when it is determined that the end of the process is not notified (S404: No), the control part 85 determines whether or not the change of the set temperature of the substrate W is instructed from the control device (S405). When it is determined that the change of the set temperature of the substrate W is not instructed (S405: No), the control part 85 executes the process of step S401 again. On the other hand, when it is determined that the change of the set temperature of the substrate W is instructed (S405: Yes), the control part 85 executes the process of step S400 again.

The second embodiment has been described above. Also in the present embodiment, it is possible to reduce the size of the substrate processing apparatus 1.

[Others]

The techniques disclosed herein are not limited to the above-described embodiments, and many modifications may be made within the scope of the gist thereof.

For example, in the above-described embodiments, the apparatus for etching the substrate W using plasma has been described as the substrate processing apparatus 1 by way of example. However, the disclosed technique is not limited thereto. For example, the disclosed technique may be applied to an apparatus that performs a process such as film formation, film modification or the like using plasma.

Further, in the above-described embodiments, there has been described the substrate processing apparatus 1 that performs a process using capacitively coupled plasma (CCP) as an example of the plasma source. However, the plasma source is not limited thereto. Examples of the plasma source other than the capacitively coupled plasma may include inductively coupled plasma (ICP), microwave excited surface wave plasma (SWP), electron cyclotron resonance plasma (ECP), helicon wave excited plasma (HWP), and the like.

According to various aspects and embodiments of the present disclosure, it is possible to reduce the size of the substrate processing apparatus.

It should be noted that the embodiments disclosed herein are exemplary in all respects and are not restrictive. Indeed, the above-described embodiments may be implemented in a variety of forms. Further, the above-described embodiments may be omitted, replaced or changed in various forms without departing from the scope of the appended claims and the spirit thereof.

What is claimed is:

1. A substrate processing apparatus for processing a substrate using plasma, comprising:
a chamber in which the substrate is accommodated; and
a stage arranged inside the chamber and configured to mount the substrate thereon,
wherein the stage includes: a base formed by a conductor and configured to allow RF (Radio Frequency) power to flow through the conductor; a substrate holding part provided on the base and configured to hold the substrate; a plurality of heaters provided in the substrate holding part; a heater control part provided inside the base and configured to control electric power to be supplied to each of the plurality of heaters; and an RF filter provided outside the base and connected to a wiring for supplying the electric power to each of the plurality of heaters, and
the RF filter is provided in common for the plurality of heaters.

2. The substrate processing apparatus of claim 1, wherein the stage further includes a plurality of resistors each arranged in the vicinity of each of the plurality of heaters and configured to have a resistance value that changes depending on a temperature, and a plurality of measurement parts configured to measure the resistance value of each of the plurality of resistors, and
the heater control part is configured to control the supply of the electric power to the corresponding heater of the plurality of heaters based on the temperature corresponding to the resistance value measured by each of the plurality of measurement parts.

3. The substrate processing apparatus of claim 2, wherein each of the plurality of resistors is arranged between the corresponding heater of the plurality of heaters and the base.

4. The substrate processing apparatus of claim 3, wherein the heater control part is configured to correct the temperature corresponding to the resistance value of each of the plurality of resistors based on a temperature difference between the temperature corresponding to the resistance value of each of the plurality of resistors and the temperature of the substrate at a position corresponding to a position where each of the plurality of resistors is provided, and control the supply of the electric power to the corresponding heater of the plurality of heaters based on the corrected temperature.

5. The substrate processing apparatus of claim 4, wherein each of the plurality of resistors is a thermistor.

6. The substrate processing apparatus of claim 2, wherein the heater control part is configured to correct the temperature corresponding to the resistance value of each of the plurality of resistors based on a temperature difference between the temperature corresponding to the resistance value of each of the plurality of resistors and the temperature of the substrate at a position corresponding to a position where each of the plurality of resistors is provided, and control the supply of the electric power to the corresponding heater of the plurality of heaters based on the corrected temperature.

7. The substrate processing apparatus of claim 2, wherein each of the plurality of resistors is a thermistor.

8. A stage arranged inside a chamber of a substrate processing apparatus for processing a substrate using plasma and configured to mount the substrate thereon, comprising:
a base formed by a conductor and configured to allow RF power to flow through the conductor;
a substrate holding part provided on the base and configured to hold the substrate;
a plurality of heaters provided in the substrate holding part;
a heater control part provided inside the base and configured to control electric power to be supplied to each of the plurality of heaters; and
an RF filter provided outside the base and connected to a wiring for supplying the electric power to each of the plurality of heaters,
wherein the RF filter is provided in common for the plurality of heaters.
